(19) United States
(12) Patent Application Publication
(10) Pub. No.: US 2016/0133733 A1
(43) Pub. Date: May 12, 2016

(54) POWER SEMICONDUCTOR COMPONENT AND MANUFACTURING METHOD THEREOF

(71) Applicant: MOSEL VITELIC INC., Hsinchu (TW)

(72) Inventor: Chien-Ping Chang, Hsinchu (TW)

(21) Appl. No.: 14/926,962

(22) Filed: Oct. 29, 2015

(30) Foreign Application Priority Data
Nov. 12, 2014 (TW) 103139147

(51) Int. Cl. H01L 29/739; H01L 21/324; H01L 29/66

(52) U.S. Cl. CPC H01L 29/7396; H01L 29/66333; H01L 21/324

(57) ABSTRACT

A power semiconductor component includes a semiconductor substrate, a MOS layer, a N-type buffer layer, a P-type injection layer, a backside trench layer and a collector metal layer. The MOS layer is formed on a first surface of the semiconductor substrate for defining a N-type high-resistance layer. The N-type buffer layer is formed on the second surface through ion implanting. The P-type injection layer is formed on the N-type buffer layer through ion implanting and at least one time of ion laser annealing. The backside trench layer is formed on the P-type injection layer and partial N-type buffer layer. The collector metal layer is formed on the P-type injection layer and the backside trench layer, so the collector metal layer, the P-type injection layer and the N-type buffer layer are shorted for forming a structure of a reverse diode in parallel, thereby reducing the area and the cost of encapsulation.

### FIELD OF THE INVENTION

The present invention relates to a power semiconductor component, and more particularly to a power semiconductor component having a structure of a reverse diode and a manufacturing method thereof.

### BACKGROUND OF THE INVENTION

In recent years, with the growing of the technologies, lot types of electronic products are produced. The high-tech electronic devices are deeply combined with human's daily life. For example, each of the panels and the global positioning systems of automobiles, smart phones, tablet PCs, variety toys and remote-controlled apparatuses is part of the technology life of human nowadays. The mainly necessary elements in electronic devices are semiconductor elements, such like power semiconductors, transistors, amplifiers and switches, especially the power semiconductors are much more fabricated in industry.

For example, one of the common power semiconductors is an insulated gate bipolar transistor (hereinafter “IGBT”). The basic encapsulation of an IGBT is a power semiconductor with three terminals. The characteristics of IGBTs include high efficiency and high switching speed. Generally, IGBTs are developed to replace the bipolar junction transistors (or called BJTs). IGBTs have both the characteristics of field effect transistors (or called FET) and bipolar transistors, so the IGBTs can withstand high current load, the gate can be easily driven and the turn-on voltage drop is low. Under this circumstance, the common uses of IGBTs are applied to high-capacity power devices like switching power supplies, motor controllers and induction cookers.

Please refer to FIG. 1 and FIG. 2. FIG. 1 schematically illustrates the structure of a conventional insulated gate bipolar transistor of the prior art. FIG. 2 schematically illustrates the encapsulation of a conventional insulated gate bipolar transistor and a diode connected in parallel of the prior art. As shown in FIG. 1 and FIG. 2, when the conventional IGBT is utilized in some circuit, such like a inductance loading circuit, a reverse diode 2 must be connected with the circuit in parallel, so that the reverse current is passed through and the insulated gate bipolar transistor 1 is protected. In the prior art, the chip of the independent IGBT 1 and the chip of the independent diode 2 are encapsulated as an insulated gate bipolar transistor component 3. However, the encapsulation area will be increased by this way, and so does the encapsulation cost.

Please refer to FIG. 3. FIG. 3 schematically illustrates the structure of a conventional reverse conducting insulated gate bipolar transistor of the prior art. As shown in FIG. 3, for economizing the components of the circuit, an IGBT component combined by an IGBT and a diode is developed, and the IGBT component is called “reverse conducting IGBT” (or RC-IGBT) in general. A RC-IGBT has the function of bidirectional conduction (i.e. forward conduction and reverse conduction), so that the amount of the encapsulated chips and wires is reduced, thereby reducing the manufacturing cost of the component. The conventional techniques provide a common method of forming P/N staggered patterns on the bottom of an IGBT through photolithography and ion implanting. The P-type region and the N-type region are formed on the same plane and shorted by the metal contact, so that a reverse conducting IGBT component 4 is formed with a built-in diode in circuit view.

Nevertheless, since the P/N staggered patterns of the reverse conducting IGBT component is formed by mask and ion implanting, the lateral diffusion issue is prone to be occurred through the ion annealing process, and the implanting profile is difficult to be controlled, thereby causing the component characteristics to be unstable.

There is a need of providing a power semiconductor component and a manufacturing method thereof to obviate the drawbacks encountered from the prior art.

### SUMMARY OF THE INVENTION

The present invention provides a power semiconductor component and a manufacturing method thereof in order to overcome the above-mentioned drawbacks encountered by the prior arts.

The present invention also provides a power semiconductor component and a manufacturing method thereof. Since the collector metal layer, the P-type injection layer and the N-type buffer layer of the power semiconductor component are shorted for forming a structure of a reverse diode in parallel, the area and the cost of encapsulation are significantly reduced, the lateral diffusion issue through the ion annealing process is avoided, and the component characteristics are getting stable.

The present invention further provides a power semiconductor component and a manufacturing method thereof. By forming a backside trench layer and full filling the backside trench layer with the collector metal layer, the contact area of metals is increased, the contact resistance is reduced, and the attachment between the metals and the silicon substrate is enhanced.

In accordance with an aspect of the present invention, there is provided a power semiconductor component. The power semiconductor component includes a semiconductor substrate, a MOS layer, a N-type buffer layer, a P-type injection layer, a backside trench layer and a collector metal layer. The MOS layer is formed on a first surface of the semiconductor substrate for defining a N-type high-resistance layer. The N-type buffer layer is formed on the second surface through ion implanting. The P-type injection layer is formed on the N-type buffer layer through ion implanting and at least one time of ion laser annealing. The backside trench layer is formed on the P-type injection layer and a portion of the N-type buffer layer. The collector metal layer is formed on the P-type injection layer and the backside trench layer, so the collector metal layer, the P-type injection layer and the N-type buffer layer are shorted for forming a structure of a reverse diode in parallel.

In accordance with another aspect of the present invention, there is provided a manufacturing method of a power semiconductor component. The manufacturing method includes steps of providing a semiconductor substrate, forming a metal oxide semiconductor layer on a first surface of the semiconductor substrate and grinding a second surface of the semiconductor substrate, forming a N-type buffer layer on the second surface of the semiconductor substrate through ion implanting, forming a P-type injection layer on the N-type buffer layer through ion implanting, performing at least one time of an ion laser annealing process on the P-type injection layer, performing a backside photolithographic process, a backside etching process and a backside photoresist removing process for forming at least a backside trench layer on the P-type injection layer and a portion of the N-type buffer layer, and forming a collector metal layer on the P-type injection layer and the backside trench layer through metal depositing, such that the collector metal layer, the P-type injection layer and the N-type buffer layer are shorted for forming a structure of a reverse diode in parallel.

The above contents of the present invention will become more readily apparent to those ordinarily skilled in the art after reviewing the following detailed description and accompanying drawings, in which:

### BRIEF DESCRIPTION OF THE DRAWINGS

FIG. 1 schematically illustrates the structure of a conventional insulated gate bipolar transistor of the prior art;

FIG. 2 schematically illustrates the encapsulation of a conventional insulated gate bipolar transistor and a diode connected in parallel of the prior art;

FIG. 3 schematically illustrates the structure of a conventional reverse conducting insulated gate bipolar transistor of the prior art;

FIG. 4 schematically illustrates the structure of a power semiconductor component according to an embodiment of the present invention;

FIG. 5 schematically illustrates the structure of a power semiconductor component according to another embodiment of the present invention;

FIG. 6 schematically illustrates the equivalent circuit diagram of the power semiconductor component shown in FIG. 4 or FIG. 5;

FIG. 7A to FIG. 7F schematically illustrate the structures corresponding to the steps of a manufacturing method of a power semiconductor component according to an embodiment of the present invention; and

FIG. 8 schematically illustrates the flow chart of a manufacturing method of a power semiconductor component according to an embodiment of the present invention.

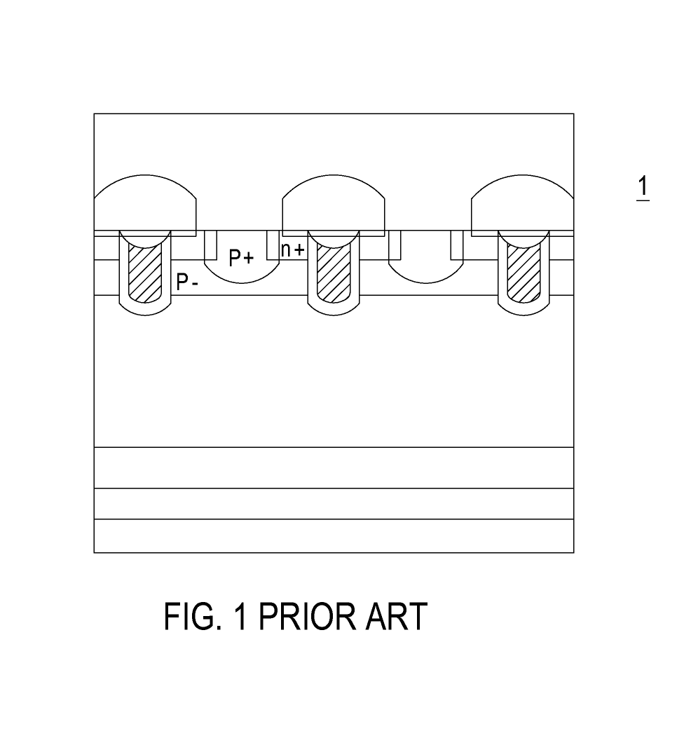

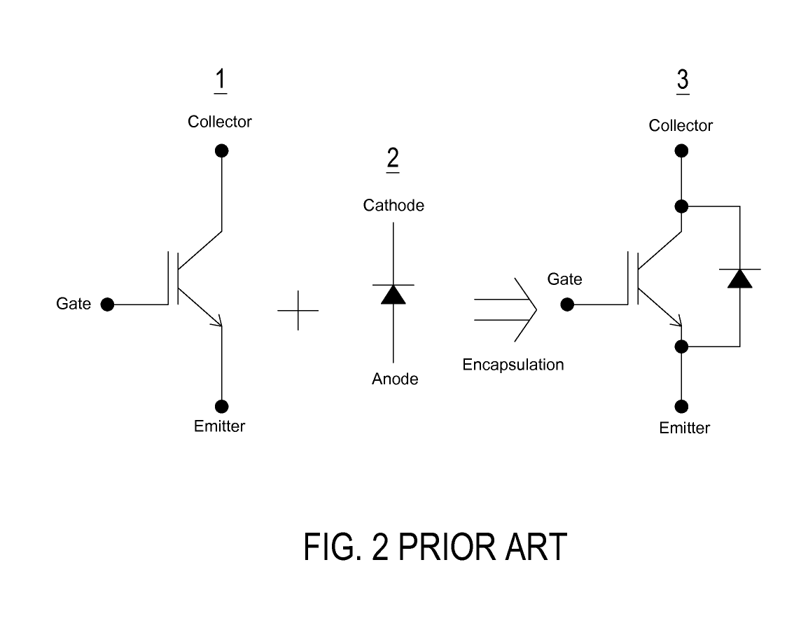

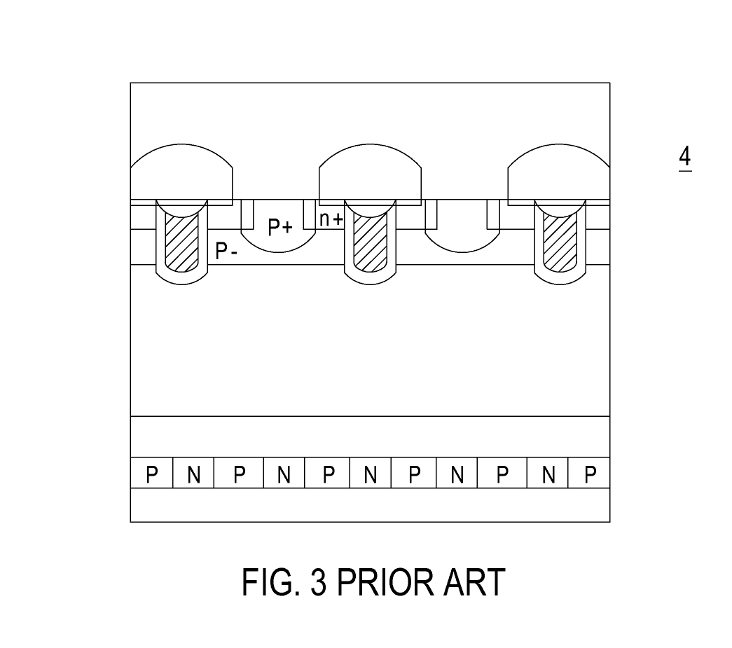

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

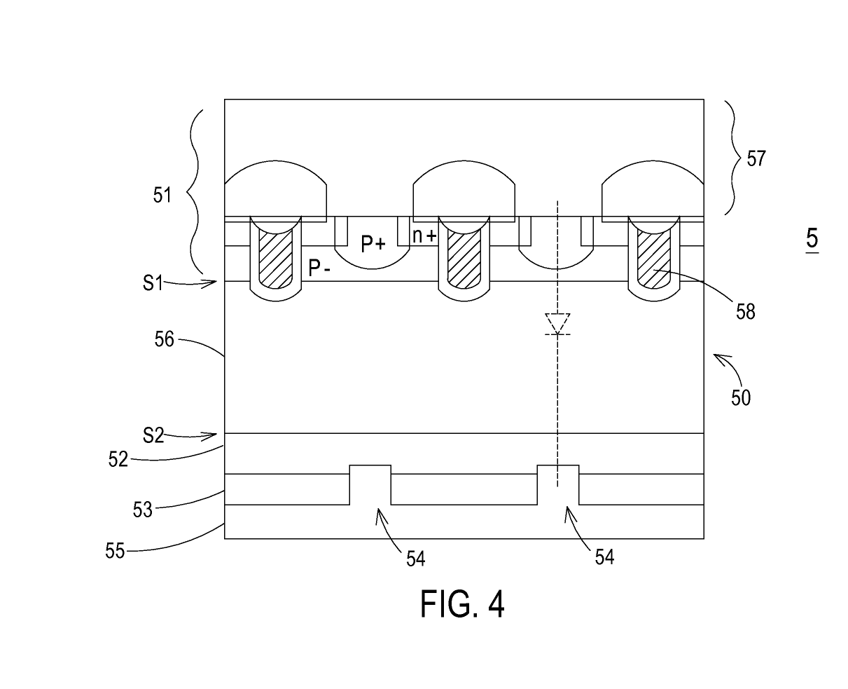

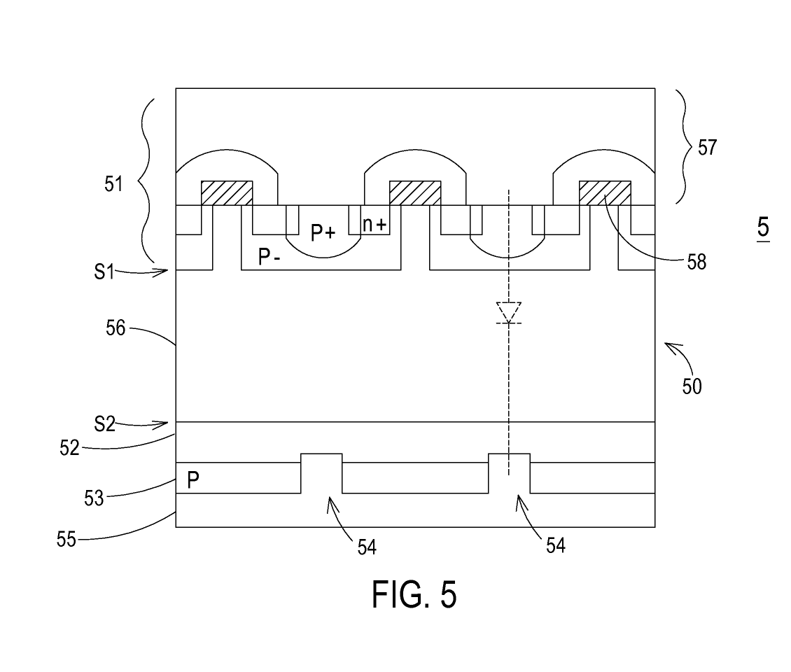

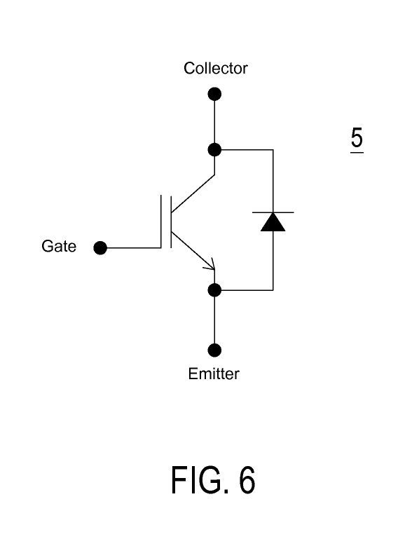

Please refer to FIG. 4, FIG. 5 and FIG. 6. FIG. 4 schematically illustrates the structure of a power semiconductor component according to an embodiment of the present invention. FIG. 5 schematically illustrates the structure of a power semiconductor component according to another embodiment of the present invention. FIG. 6 schematically illustrates the equivalent circuit diagram of the power semiconductor component shown in FIG. 4 or FIG. 5. As shown in FIG. 4, FIG. 5 and FIG. 6, the power semiconductor component 5 of the present invention at least includes a semiconductor substrate 50, a metal-oxide semiconductor (hereinafter “MOS”) layer 51, a N-type buffer layer 52, a P-type injection layer 53, a backside trench layer 54 and a collector metal layer 55. The semiconductor substrate 50 is a N-type high-resistance substrate. The semiconductor substrate 50 has a first surface S1 and a second surface S2, among which the first surface S1 and the second surface S2 are for example the front surface and the back surface of the semiconductor substrate 50, but not limited thereto. The MOS layer 51 is not limited to a trench MOS layer (as shown in FIG. 4) or a planar MOS layer (as shown in FIG. 5), formed on the first surface Si of the semiconductor substrate 50 for defining a N-type high-resistance layer 56 of the semiconductor substrate 50. The N-type high-resistance layer 56 is used for conducting between the electrons and the electron holes and withstanding high voltage.

In some embodiments, the N-type buffer layer 52 is formed on the second surface S2 through ion implanting for buffering the electric field and adjusting the concentration of electron hole injection. By ion implanting N-type impurities like P31 or As75 on the second surface S2, which is for example the back surface of the semiconductor substrate 50, the electron hole injection efficiency and the width of the depletion region can be adjusted by changing the implant concentration, and the process flexibility is enhanced. Additionally, the P-type injection layer 53 is formed on the N-type buffer layer 52 through ion implanting and at least one time of ion laser annealing for providing electron hole injection. By ion implanting P-type impurities like B11 on the second surface S2, the electron hole injection efficiency can be adjusted by changing the implant concentration.

Furthermore, at least a backside trench layer 54 is formed on the P-type injection layer 53 and a portion of the N-type buffer layer 52 by at least a backside photolithographic process, at least a backside etching process and at least a backside photoresist removing process. After the backside trench layer 54 is formed, the collector metal layer 55 is formed on the P-type injection layer 53 and the backside trench layer 54 by at least a backside metal depositing process, among which the backside trench layer 54 is full-filled by the collector metal layer 55, so the collector metal layer 55, the P-type injection layer 53 and the N-type buffer layer 52 are shorted for forming a structure of a reverse diode in parallel (shown as dashed lines in the drawings). As a result, the area and the cost of encapsulation are significantly reduced, the lateral diffusion issue through the ion annealing process is avoided, and the component characteristics are getting stable. Meanwhile, by forming the backside trench layer 54 and full filling the backside trench layer 54 with the collector metal layer 55, the contact area of metals is increased, the contact resistance is reduced, and the attachment between the metals and the silicon substrate is enhanced.

In some embodiments, the power semiconductor component 5 further includes an emitter metal layer 57, among which the emitter metal layer 57 is formed on the MOS layer 51, and the emitter metal layer 57 is formed opposite to the collector metal layer 55. In addition, a gate layer 58 of the power semiconductor component 5 is shown as slash region in the embodiments shown in FIG. 4 and FIG. 5, and the equivalent circuit diagram of the power semiconductor component 5 is shown as FIG. 6.

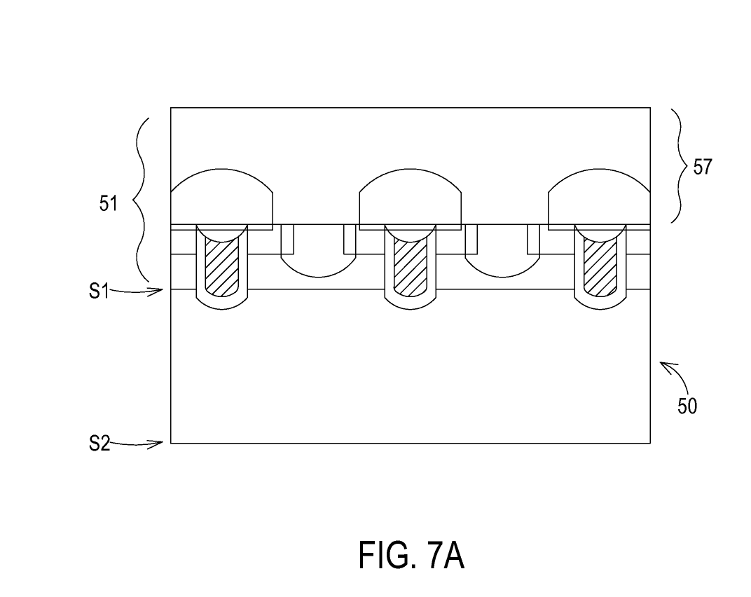

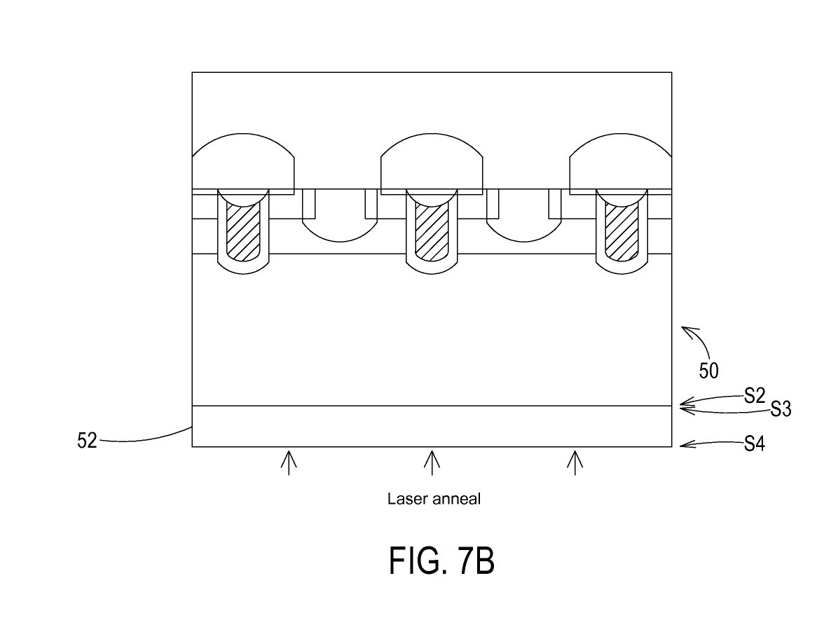

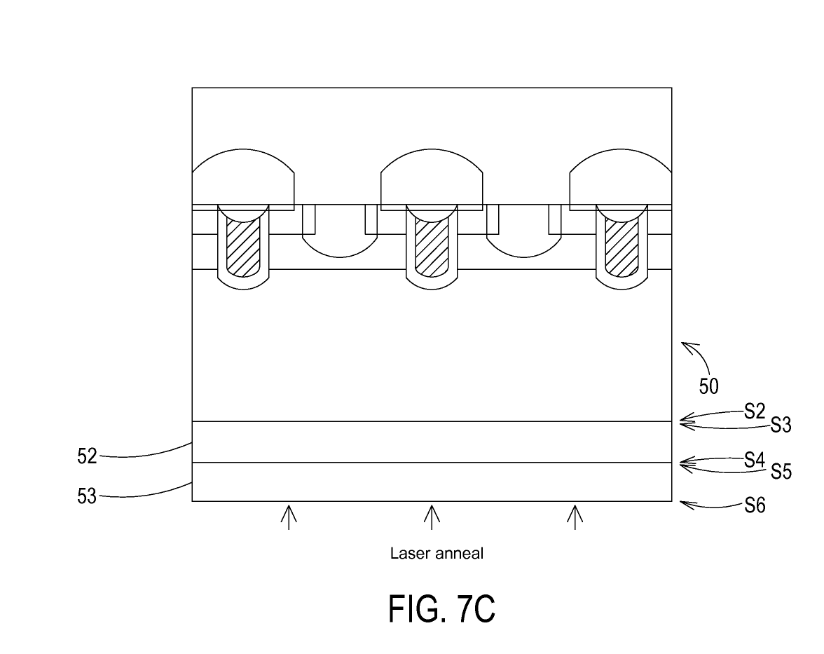

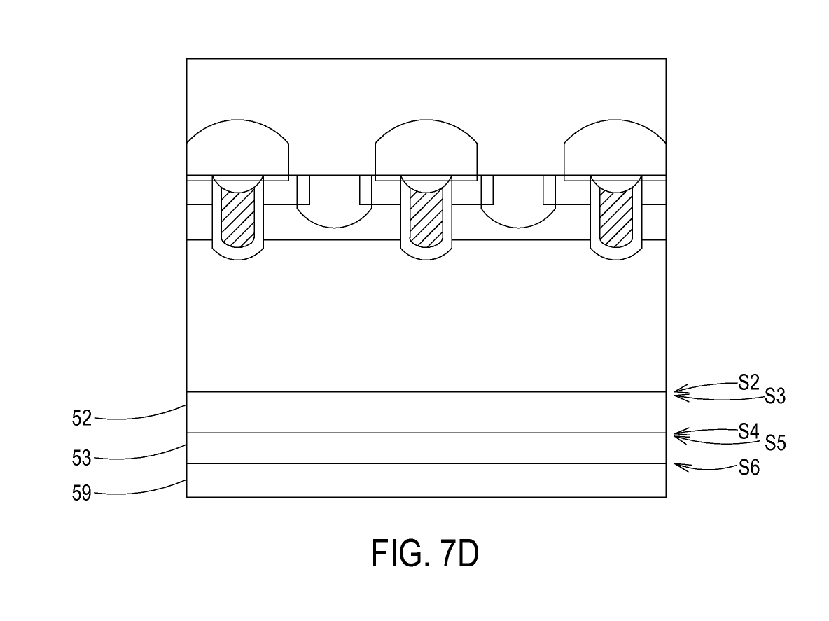

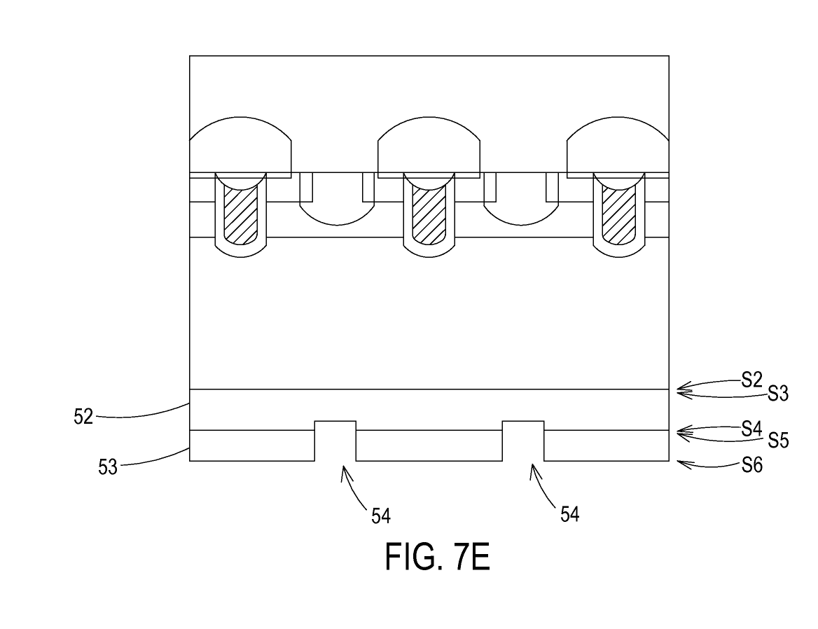

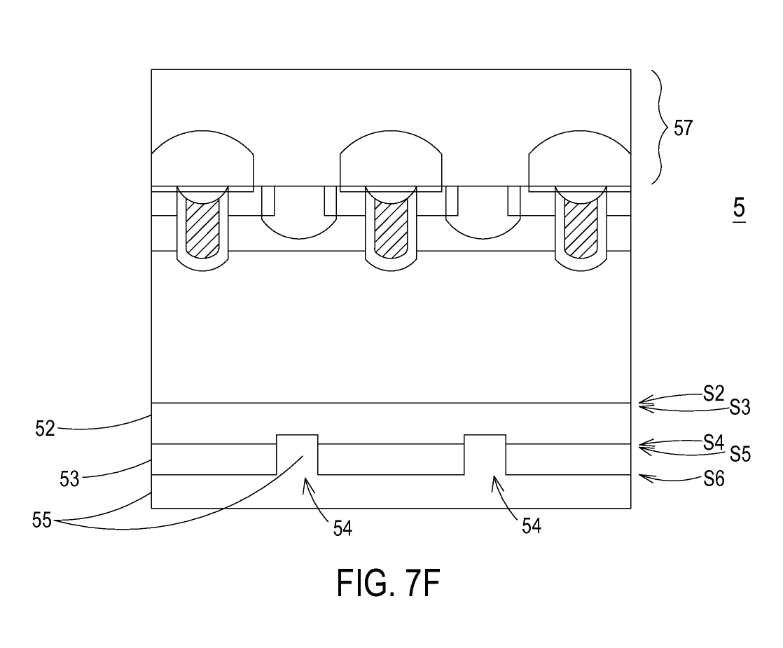

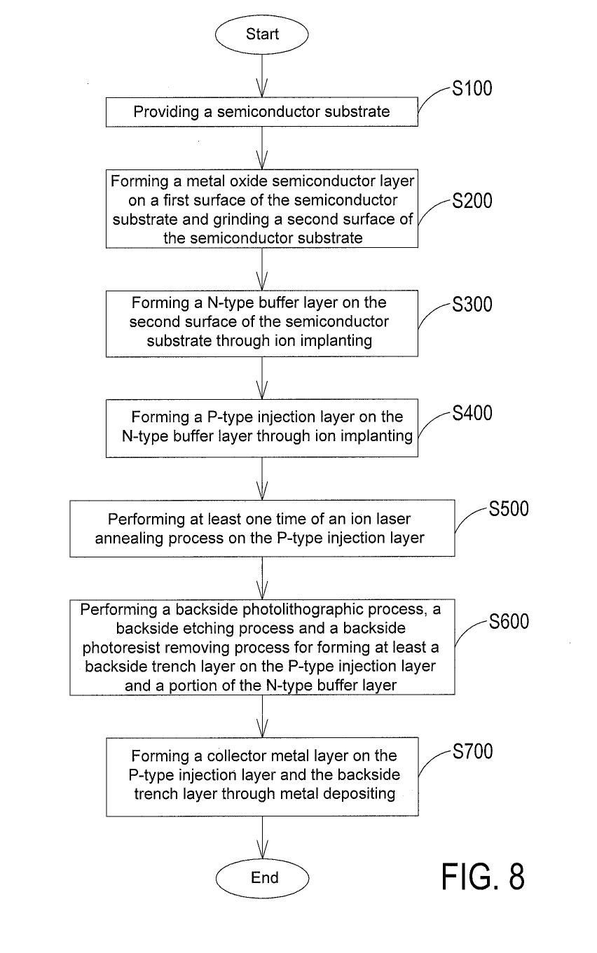

Please refer to FIGS. 7A-7F and FIG. 8. FIG. 7A to FIG. 7F schematically illustrate the structures corresponding to the steps of a manufacturing method of a power semiconductor component according to an embodiment of the present invention. FIG. 8 schematically illustrates the flow chart of a manufacturing method of a power semiconductor component according to an embodiment of the present invention. The manufacturing method of the power semiconductor component 5 of the present invention includes steps as follows. First of all, as shown in FIG. 7A, step S100 and step S200, providing a semiconductor substrate 50, and forming a metal oxide semiconductor layer 51 on a first surface S1 of the semiconductor substrate 50. The metal oxide semiconductor layer 51 is similar with the MOS layer 51 of the embodiments mentioned above, and is not redundantly described herein. It should be noted that all of the MOS layers having the similar advantages and structures with MOS layer 51 of the present invention are taught by the present invention. After forming the MOS layer 51 on the first surface S1, which is for example a front surface of the semiconductor substrate 50, the emitter metal layer 57 can be formed in this step, and a further step of grinding the second surface S2 of the semiconductor substrate 50 (i.e. a backside grinding process) is proceeded for reducing the thickness of the semiconductor substrate 50 or the wafer.

Next, as shown in FIG. 7B and step S300, after grinding the second surface S2 of the semiconductor substrate 50, forming a N-type buffer layer 52 on the second surface S2 of the semiconductor substrate 50 through ion implanting. An example of the implanting ions includes but not limited to the N-type impurities like P31 or As75. The N-type buffer layer 52 has a third surface S3 and a fourth surface S4, among which the third surface S3 is in contact with the second surface S2 of the semiconductor substrate 50. After forming the N-type buffer layer 52, selectively performing a surface treating of the N-buffer layer 52 through laser beams, which is for example laser annealing the N-type buffer layer 52 (i.e. a backside laser annealing process), but not limited thereto.

Then, as shown in FIG. 7C and step S400, after the laser annealing on the N-type buffer layer 52, forming a P-type injection layer 53 on the fourth surface S4 of the N-type buffer layer 52 through ion implanting. An example of the implanting ions includes but not limited to the P-type impurities like B11. The P-type injection layer 53 has a fifth surface S5 and a sixth surface S6, among which the fifth surface S5 is in contact with the fourth surface S4 and the sixth surface S6 is opposite to the fifth surface S5. In particular, the sixth surface S6 and the fifth surface S5 are disposed on the two different sides of the P-type injection layer 53. After forming the P-type injection layer 53, surface treating the P-type injection layer 53 through laser beams, which is for example laser annealing the P-type injection layer 53 (i.e. a backside laser annealing process), but not limited thereto.

Next, as shown in FIG. 7D, FIG. 7E and step S500, after the laser annealing on the P-type injection layer 53, performing at least a backside photolithographic process, at least a backside etching process and at least a backside photoresist removing process. In particular, a photoresist layer 59 is coated on the sixth surface S6 of the P-type injection layer 53, the pattern of the backside trench layer 54 is defined by the backside photolithographic process, and then the photoresist layer 59 is removed by the backside etching process and the backside photoresist removing process, such that the backside trench layer 54 is formed on the P-type injection layer 53 and a portion of the N-type buffer layer 52. In other words, the backside trench layer 54 is formed on the fourth surface S4 from the backside.

At last, as shown in FIG. 7F and step S600, forming a collector metal layer 55 on the P-type injection layer 53 and the backside trench layer 54 through metal depositing. The collector metal layer 55 is formed on the sixth surface S6 of the P-type injection layer 53, the backside trench layer 54 is full filled by the collector metal layer 55, and the collector metal layer 55 is disposed opposite to the emitter metal layer 57. In other words, the collector metal layer 55 is disposed on the other side of the emitter metal layer 57 in reference of the total power semiconductor component 5, which means that the emitter metal layer 57 is formed opposite to the collector metal layer 55.

From the above description, the present invention provides a power semiconductor component and a manufacturing method thereof. Since the collector metal layer, the P-type injection layer and the N-type buffer layer of the power semiconductor component are shorted for forming a structure of a reverse diode in parallel, the area and the cost of encapsulation are significantly reduced, the lateral diffusion issue through the ion annealing process is avoided, and the component characteristics are getting stable. Meanwhile, by forming a backside trench layer and full filling the backside trench layer with the collector metal layer, the contact area of metals is increased, the contact resistance is reduced, and the attachment between the metals and the silicon substrate is enhanced.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A power semiconductor component, comprising:
a semiconductor substrate having a first surface and a second surface;
a metal oxide semiconductor layer formed on the first surface for defining a N-type high-resistance layer of the semiconductor substrate;
a N-type buffer layer formed on the second surface through ion implanting; and
a P-type injection layer formed on said N-type buffer layer through ion implanting and at least one time of ion laser annealing;
at least a backside trench layer formed on the P-type injection layer and a portion of the N-type buffer layer; and
a collector metal layer formed on the P-type injection layer and the backside trench layer, such that the collector metal layer, the P-type injection layer and the N-type buffer layer are shorted for forming a structure of a reverse diode in parallel.

2. The power semiconductor component according to claim 1, wherein the backside trench layer is full-filled by the collector metal layer.

3. The power semiconductor component according to claim 1, wherein the N-type buffer layer has a third surface and a fourth surface, and wherein the third surface is in contact with the second surface, and the P-type injection layer is formed on the fourth surface.

4. The power semiconductor component according to claim 3, wherein the P-type injection layer has a fifth surface and a sixth surface, and wherein the fifth surface is in contact with the fourth surface, and the sixth surface is opposite to the fifth surface.

5. The power semiconductor component according to claim 4 further comprising an emitter metal layer, wherein the emitter metal layer is formed on the metal oxide semiconductor layer, the collector metal layer is formed on the sixth surface, and the emitter metal layer is formed opposite the fifth surface.

6. The power semiconductor component according to claim 1, wherein the backside trench layer is formed by at least a backside photolithographic process, at least a backside etching process and at least a backside photoresist removing process, and the collector metal layer is formed by at least a backside metal depositing process.

7. The power semiconductor component according to claim 1, wherein the metal oxide semiconductor layer is a trench metal oxide semiconductor layer or a planar metal oxide semiconductor layer.

8. A manufacturing method of a power semiconductor component, comprising steps of:
(a) providing a semiconductor substrate;
(b) forming a metal oxide semiconductor layer on a first surface of the semiconductor substrate and grinding a second surface of the semiconductor substrate;
(c) forming a N-type buffer layer on the second surface of the semiconductor substrate through ion implanting;
(d) forming a P-type injection layer on the N-type buffer layer through ion implanting;
(e) performing at least one time of an ion laser annealing process on the P-type injection layer;
(f) performing a backside photolithographic process, a backside etching process and a backside photoresist removing process for forming at least a backside trench layer on the P-type injection layer and a portion of the N-type buffer layer; and
(g) forming a collector metal layer on the P-type injection layer and the backside trench layer through metal depositing, such that the collector metal layer, the P-type injection layer and the N-type buffer layer are shorted for forming a structure of a reverse diode in parallel.

9. The manufacturing method according to claim 8, wherein the backside trench layer is full-filled by the collector metal layer.

10. The manufacturing method according to claim 8, wherein the step (c) further comprises a step, after the step (c), of (h) selectively performing a laser annealing process on the N-type buffer layer.
